(19) United States
(12) Patent Application Publication
(10) Pub. No.: US 2015/0115433 A1
(43) Pub. Date: Apr. 30, 2015

(54) SEMICONDUCOR DEVICE AND METHOD OF MANUFACTURING THE SAME

(71) Applicant: Bridge Semiconductor Corporation, Taipei City (TW)

(72) Inventors: Charles W.C. LIN, Singapore (SG); Chia-Chung WANG, Hsinchu (TW)

(21) Appl. No.: 14/449,201

(22) Filed: Aug. 1, 2014

Related U.S. Application Data
(63) Continuation-in-part of application No. 14/190,457, filed on Feb. 26, 2014.
(60) Provisional application No. 61/895,506, filed on Oct. 25, 2013.
(60) Provisional application No. 61/895,506, filed on Oct. 25, 2013.

(51) Int. Cl. H01L 23/00; H01L 23/34

(52) U.S. Cl. CPC H01L 24/19; H01L 24/81; H01L 23/34; H01L 24/20; H01L 2924/156; H01L 2924/161
USPC 257/712; 438/122

(57) ABSTRACT

The present invention relates to a method of making a semiconductor device having a chip embedded in a heat spreader and electrically connected to a hybrid substrate. In accordance with a preferred embodiment, the method is characterized by the step of attaching a chip-on-interposer subassembly on a heat spreader using an adhesive with the chip inserted into a cavity of the heat spreader. The heat spreader provides thermal dissipation and the interposer provides a CTE-matched interface and primary fan-out routing for the chip.

### CROSS REFERENCE TO RELATED APPLICATIONS

This application is a continuation-in-part of U.S. application Ser. No. 14/190,457 filed Feb. 26, 2014, which is incorporated by reference. This application and U.S. application Ser. No. 14/190,457 filed Feb. 26, 2014 all claim the benefit of filing date of U.S. Provisional Application Ser. No. 61/895,506 filed Oct. 25, 2013.

### FIELD OF THE INVENTION

The present invention relates to a semiconductor device, and more particularly, to a semiconductor device having a chip embedded in a heat spreader and electrically connected to a hybrid substrate and a method of making the same.

### DESCRIPTION OF RELATED ART

The convergence of mobility, communication, and computing has created significant thermal, electrical, form-factor and reliability challenges to the semiconductor packaging industry. Despite numerous configurations for embedding semiconductor chip in wiring board or mold compound reported in the literature, many performance-related deficiencies remain. For example, the devices disclosed by U.S. Pat. Nos. 8,742,589, 8,735,222, 8,679,963, 8,453,323 may render performance degradation problems as the heat generated by the embedded chip can't be dissipated properly through the thermally insulating material such as laminate or mold compound.

Further, as these devices utilize micro-via for electrical connection of the embedded chip, it presents high stress problem on the interconnections caused by coefficient of thermal expansion (CTE) mismatch between the chip (for example, silicon is about 2.6×10⁻⁶ K⁻¹) and the buildup layers (for example, epoxy laminate is about 15×10⁻⁶ K⁻¹). As circuit density in chip increases, so does the heat generated by the chip, thereby compounding the problem with large temperature variations in its operation cycles. This thermal mismatch would cause the chip under high internal stress, eventually leading to chip cracking, delamination and device breakdown.

Another significant drawback arising from the fabrication of the above assembly structures is that the embedded chip may dislocate during encapsulation or lamination process. Incomplete metallization of micro-via due to chip dislocation as described in U.S. Pat. Nos. 8,501,544, 7,935,893 further degrades the quality of the electrical connection, thereby lowering reliability and production yield of the fabricated assembly.

For the reasons stated above, and for other reasons stated below, a significant need exists to develop a new apparatus and method to interconnect embedded chip without using micro-via at I/O pad to improve chip-level reliability and restrain from the use of mold compound or laminate to prevent overheating of chip that creates enormous concerns in device electrical performance.

### SUMMARY OF THE INVENTION

The present invention has been developed in view of such a situation, and a primary objective of the present invention is to provide a semiconductor device in which a chip is interconnected to a low CTE interposer by a plurality of bumps so as to resolve CTE mismatch and positional recognition problems between the chip and interconnect circuitry, thereby improving production yield and reliability of the semiconductor device.

Another objective of the present invention is to provide a semiconductor device in which a chip is enclosed in a heat spreader so as to effectively dissipate the heat generated by the chip, thereby improving signal integrity and electrical performance of the device.

In accordance with the foregoing and other objectives, the present invention proposes a semiconductor device having a chip, a heat spreader and a hybrid substrate comprising an inorganic interposer and a resin buildup circuitry. The heat spreader, enclosing the chip, provides heat dissipation pathway for the chip. The CTE-compensated inorganic interposer, interconnected to the chip by bumps, provides primary fan-out routing for the chip so that the internal stresses in the chip and the possible bond pad disconnection induced by CTE mismatch can be avoided. The resin buildup circuitry, adjacent to the heat spreader and the interposer, provides secondary fan-out routing and has a patterned array of terminal pads that matches the next level assembly wiring board.

In one aspect, the present invention provides a method of making an semiconductor device, comprising the steps of: providing a chip; providing an inorganic interposer that includes through vias, a first surface, a second surface opposite to the first surface, first contact pads on the first surface and second contact pads on the second surface, wherein the through vias electrically couple the first contact pads and the second contact pads; electrically coupling the chip to the first contact pads of the inorganic interposer by a plurality of bumps to provide a chip-on-interposer subassembly; providing a heat spreader with a cavity; attaching the chip-on-interposer subassembly on the heat spreader using an adhesive with the chip inserted into the cavity and the inorganic interposer laterally extending beyond the cavity; and then forming a buildup circuitry on the heat spreader and the second surface of the inorganic interposer, including electrically coupling the buildup circuitry to the second contact pads of the inorganic interposer through a conductive via of the buildup circuitry.

Unless specific descriptions or using the term “then” between steps or steps necessarily occurring in a certain order, the sequence of the above-mentioned steps is not limited to that set forth above and may be changed or reordered according to desired design.

In another aspect, the present invention provides a semiconductor device that includes a chip, an adhesive, a heat spreader and a hybrid substrate consisting of an inorganic interposer and a buildup circuitry, wherein (i) the chip is electrically coupled to first contact pads on a first surface of the inorganic interposer by a plurality of bumps and is positioned within a cavity of the heat spreader; (ii) the inorganic interposer extends laterally beyond the cavity with the first surface of the inorganic interposer attached to a flat surface of the heat spreader that is adjacent to and laterally extends from the cavity entrance; (iii) the adhesive contacts and is sandwiched between the chip and the heat spreader and between the inorganic interposer and the heat spreader; and (iv) the buildup circuitry is disposed on the heat spreader and a second surface of the interposer opposite to the first surface and is electrically coupled to second contact pads on the second surface of the inorganic interposer through a conductive via of the buildup circuitry.

The method of making a semiconductor device according to the present invention has numerous advantages. For instance, forming the chip-on-interposer subassembly before attaching it to the heat spreader can ensure the chip is securely connected so that any contact pad disconnection problems inherent to micro-via process can be avoided. Inserting the chip to the cavity through the chip-on-interposer subassembly is particularly advantageous as the shape or depth of the cavity or the amount of the adhesive that needs to bind the chip would not be a critical parameter that needs tightly controlled. Additionally, the two-step forming of the hybrid substrate is beneficial as the interposer can protect the embedded chip during the buildup circuitry deposition.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, showing an interposer panel in accordance with the first embodiment of the present invention;

FIG. 3 is a cross-sectional view showing a chip with bumps mounted thereon in accordance with the first embodiment of the present invention;

FIGS. 4 and 5 are cross-sectional and top perspective views, respectively, showing a panel-scale assembly with the chips of FIG. 3 electrically coupled to the interposer panel of FIGS. 1 and 2 in accordance with the first embodiment of the present invention;

FIGS. 6 and 7 are cross-sectional and top perspective views, respectively, showing a diced state of the panel-scale assembly of FIGS. 4 and 5 in accordance with the first embodiment of the present invention;

FIGS. 8 and 9 are cross-sectional and top perspective views, respectively, showing a chip-on-interposer subassembly corresponding to a diced unit in FIGS. 6 and 7 in accordance with the first embodiment of the present invention;

FIGS. 10 and 11 are cross-sectional and bottom perspective views, respectively, showing a heat spreader in accordance with the first embodiment of the present invention;

FIGS. 12 and 13 are cross-sectional and bottom perspective views, respectively, showing a state in which an adhesive is dispensed on the heat spreader of FIGS. 10 and 11 in accordance with the first embodiment of the present invention;

FIGS. 14 and 15 are cross-sectional and bottom perspective views, respectively, showing a state in which the chip-on-interposer subassemblies of FIGS. 8 and 9 are attached on the heat spreader of FIGS. 12 and 13 in accordance with the first embodiment of the present invention;

FIGS. 16 and 17 are cross-sectional and bottom perspective views, respectively, showing a state in which the structure of FIGS. 14 and 15 is provided with another adhesive in accordance with the first embodiment of the present invention;

FIGS. 18 and 19 are cross-sectional and bottom perspective views, respectively, showing a state in which excess adhesive is removed from the structure of FIGS. 16 and 17 in accordance with the first embodiment of the present invention;

FIG. 20 is a cross-sectional view showing a state in which laminated layers are disposed on the structure of FIG. 18 in accordance with the first embodiment of the present invention;

FIG. 21 is a cross-sectional view showing a state in which the structure of FIG. 20 is provided with via openings in accordance with the first embodiment of the present invention;

FIG. 22 is a cross-sectional view showing a state in which the structure of FIG. 21 is provided with conductive traces in accordance with the first embodiment of the present invention;

FIG. 23 is a cross-sectional view showing a state in which laminated layers are disposed on the structure of FIG. 22 in accordance with the first embodiment of the present invention;

FIG. 24 is a cross-sectional view showing a state in which the structure of FIG. 23 is provided with via openings in accordance with the first embodiment of the present invention;

FIG. 25 is a cross-sectional view showing with a state in which the structure of FIG. 24 is provided with conductive traces to finish the fabrication of a semiconductor device in accordance with the first embodiment of the present invention;

FIG. 26 is a cross-sectional view showing a heat spreader in accordance with the second embodiment of the present invention;

FIG. 27 is a cross-sectional view showing a state in which an adhesive is dispensed on the heat spreader of FIG. 26 in accordance with the second embodiment of the present invention;

FIG. 28 is a cross-sectional view showing a state in which the chip-on-interposer subassembly of FIG. 8 is attached on the heat spreader of FIG. 27 in accordance with the second embodiment of the present invention;

FIG. 29 is a cross-sectional view showing a state in which the structure of FIG. 28 is provided with another adhesive in accordance with the second embodiment of the present invention;

FIG. 30 is a cross-sectional view showing a state in which excess adhesive is removed from the structure of FIG. 29 in accordance with the second embodiment of the present invention;

FIG. 31 is a cross-sectional view showing a state in which laminated layers are disposed on the structure of FIG. 30 in accordance with the second embodiment of the present invention;

FIG. 32 is a cross-sectional view showing a state in which the structure of FIG. 31 is provided with via openings in accordance with the second embodiment of the present invention;

FIG. 33 is a cross-sectional view showing with a state in which the structure of FIG. 32 is provided with conductive traces to finish the fabrication of a semiconductor device in accordance with the second embodiment of the present invention;

FIG. 34 is a cross-sectional view showing a laminate substrate in accordance with the third embodiment of the present invention;

FIG. 35 is a cross-sectional view showing a state in which the laminate substrate of FIG. 34 is processed to form an alignment guide in accordance with the third embodiment of the present invention;

FIG. 36 is a cross-sectional view showing a laminate substrate with openings in accordance with the third embodiment of the present invention;

FIG. 37 is a cross-sectional view showing a state in which the laminate substrate of FIG. 36 is processed to form an alignment guide in accordance with the third embodiment of the present invention;

FIG. 38 is a cross-sectional view showing a state in which the laminate substrate of FIG. 35 is provided with a cavity to finish the fabrication of a heat sink in accordance with the third embodiment of the present invention;

FIG. 39 is a cross-sectional view showing a state in which a chip-on-interposer subassembly is attached on the heat spreader of FIG. 38 in accordance with the third embodiment of the present invention;

FIG. 40 is a cross-sectional view showing a state in which laminated layers are disposed on the structure of FIG. 39 in accordance with the third embodiment of the present invention;

FIG. 41 is a cross-sectional view showing a state in which the structure of FIG. 40 is provided with via openings in accordance with the third embodiment of the present invention;

FIG. 42 is a cross-sectional view showing a state in which the structure of FIG. 41 is provided with conductive traces to finish the fabrication of a semiconductor device in accordance with the third embodiment of the present invention;

FIG. 43 is a cross-sectional view showing a metal plate with an alignment guide thereon in accordance with the fourth embodiment of the present invention;

FIG. 44 is a cross-sectional view showing a state in which a base layer is disposed on the metal plate of FIG. 43 to finish the fabrication of a heat sink in accordance with the fourth embodiment of the present invention;

FIG. 45 is a cross-sectional view showing a state in which a chip-on-interposer subassembly is attached on the heat spreader of FIG. 44 in accordance with the fourth embodiment of the present invention;

FIG. 46 is a cross-sectional view showing a state in which laminated layers are disposed on the structure of FIG. 45 in accordance with the fourth embodiment of the present invention;

FIG. 47 is a cross-sectional view showing a state in which the structure of FIG. 46 is provided with via openings in accordance with the fourth embodiment of the present invention; and

FIG. 48 is a cross-sectional view showing a state in which the structure of FIG. 47 is provided with conductive traces to finish the fabrication of a semiconductor device in accordance with the fourth embodiment of the present invention.

### DETAILED DESCRIPTION OF THE PREFERRED EMBODIMENT

Hereafter, examples will be provided to illustrate the embodiments of the present invention. Advantages and effects of the invention will become more apparent from the disclosure of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

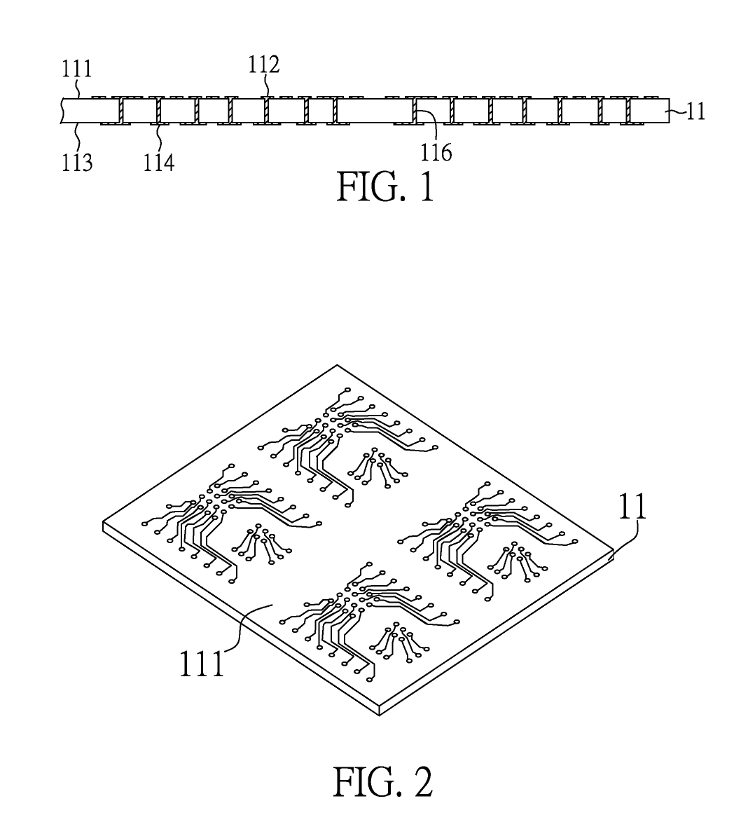

FIGS. 1-25 showing a method of making a semiconductor device that includes chips, a heat spreader and a hybrid substrate with an inorganic interposer and a resin buildup circuitry in accordance with an embodiment of the present invention.

As shown in FIG. 25, the semiconductor device 110 includes an inorganic interposer 11′, chips 13, a heat spreader 20 and a resin buildup circuitry 30. The inorganic interposer 11′ and the chips 13 are attached on the heat spreader 20 using first adhesive 191 and second adhesive 193, with the chips 13 embedded in cavities 211 of the heat spreader 20. The buildup circuitry 30 covers the inorganic interposer 11′ and the heat spreader 20 from the lower side and is electrically coupled to second contact pads 114 of the inorganic interposer 11′ through first conductive vias 317.

FIGS. 1, 3, 4, 6 and 8 are cross-sectional views showing a process of fabricating a chip-on-interposer subassembly in accordance with an embodiment of the present invention, and FIGS. 2, 5, 7 and 9 are top perspective views corresponding to FIGS. 1, 4, 6 and 8, respectively.

FIGS. 1 and 2 are cross-sectional and top perspective views, respectively, of an interposer panel 11, which includes a first surface 111, a second surface 113 opposite to the first surface 111, first contact pads 112 on the first surface 111, second contact pads 114 on the second surface 113, and through vias 116 that electrically couple the first contact pads 112 and the second contact pads 114. The interposer panel 11 is typically made of high elastic modulus inorganic material, such as silicon, glass, ceramic or graphite, and contains a pattern of traces that fan out from a fine pitch at the first contact pads 112 to a coarse pitch at the second contact pads 114.

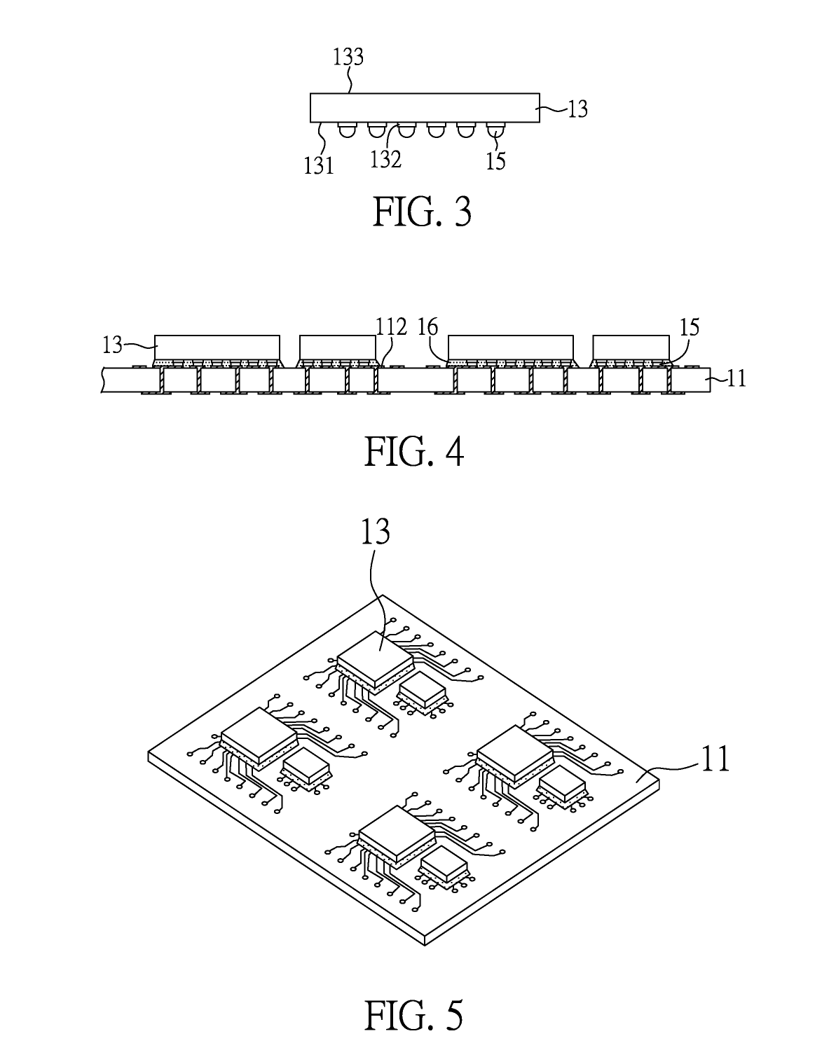

FIG. 3 is a cross-sectional view of a chip 13 with bumps 15 mounted thereon. The chip 13 includes an active surface 131, an inactive surface 133 opposite to the active surface 131, and I/O pads 132 on the active surface 131. The bumps 15 are mounted on the I/O pads 132 of the chip 13 and may be solder, gold or copper pillars.

FIGS. 4 and 5 are cross-sectional and top perspective views, respectively, of a panel-scale assembly with the chips 13 electrically coupled to the interposer panel 11. The chips 13 can be electrically coupled to the first contact pads 112 of the interposer panel 11 using the bumps 15 by thermal compression, solder reflow or thermosonic bonding. As an alternative, the bumps 15 may be first deposited on the first contact pads 112 of the interposer panel 11, and then the chips 13 are electrically coupled to the interposer panel 11 by the bumps 15. Optionally, underfill 16 can be further provided to fill the gap between the interposer panel 11 and the chips 13.

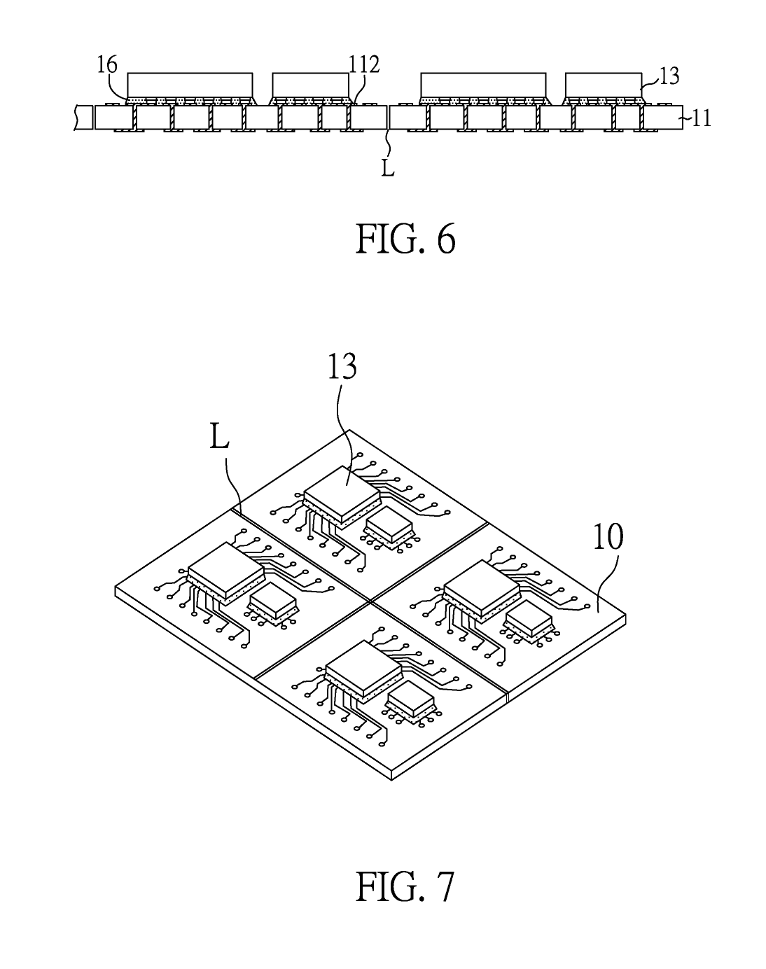

FIGS. 6 and 7 are cross-sectional and top perspective views, respectively, of the panel-scale assembly diced into individual pieces. The panel-scale assembly is singluated into individual chip-on-interposer subassemblies 10 along dicing lines “L”.

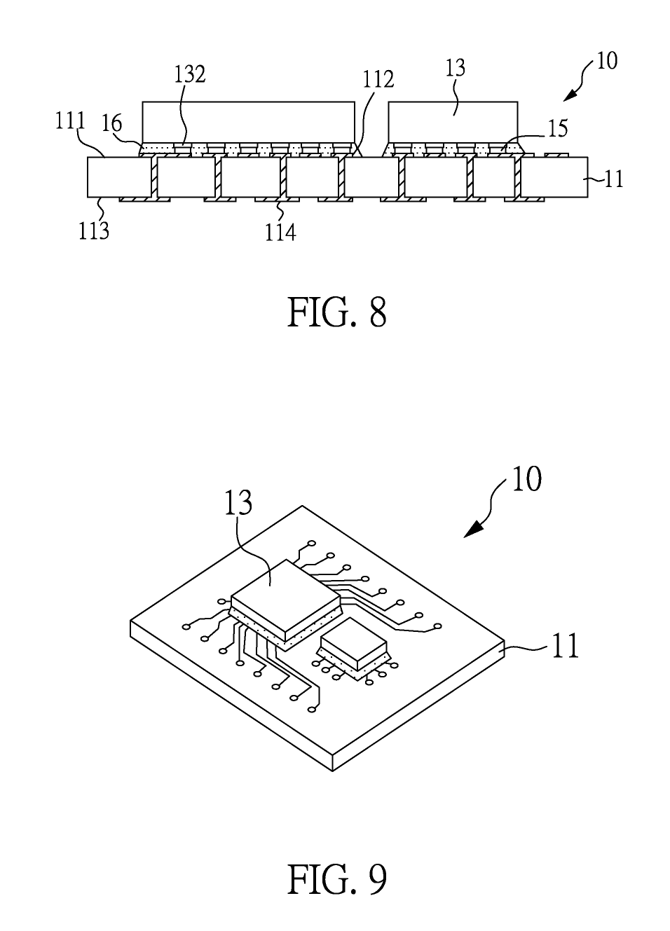

FIGS. 8 and 9 are cross-sectional and top perspective views, respectively, of the individual chip-on-interposer subassembly 10. In this illustration, the chip-on-interposer subassembly 10 includes two chips 13 electrically coupled on the diced interposer 11′. As the size and pad spacing of the second contact pads 114 of the interposer 11′ is designed to be larger than those of the chip I/O pads 132, the interposer 11′ can provide a primary fan-out routing for the chips 13 so as to ensure a higher manufacturing yield for the next level buildup circuitry interconnection. Furthermore, the interposer 11′ also provides primary electrical connections between adjoining chips 13 prior to interconnecting to the next level interconnection structure.

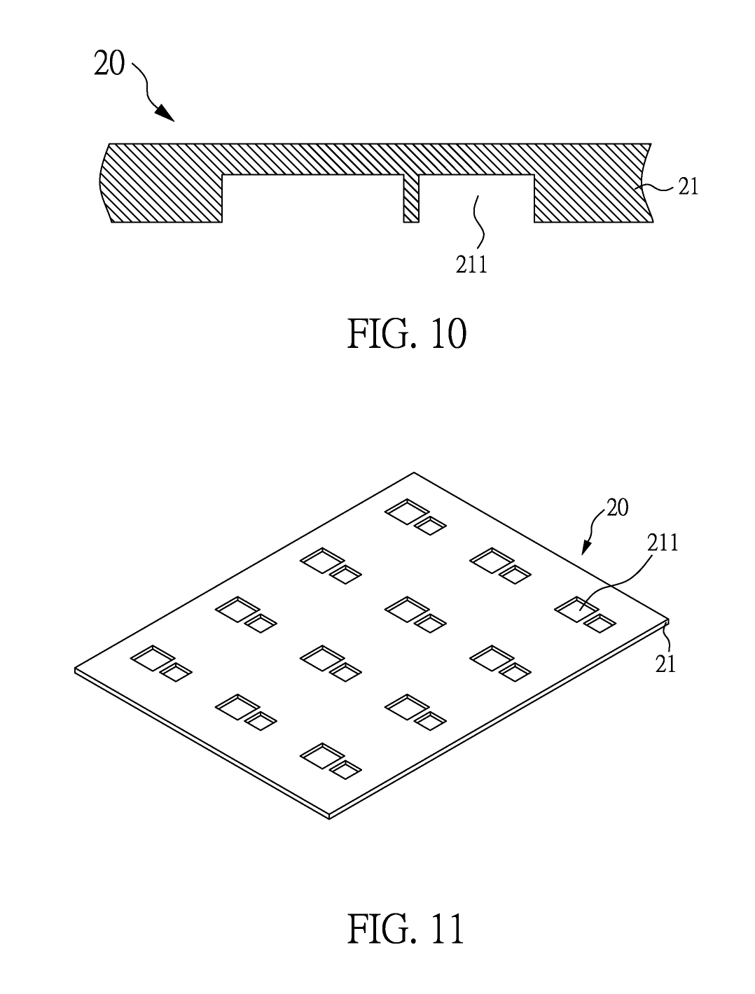

FIGS. 10 and 11 are cross-sectional and bottom perspective views, respectively, of a heat spreader 20 with cavities 211. The heat spreader 20 can be provided by forming the cavities 211 in a metal plate 21. The metal plate 21 can have a thickness of 0.1 mm to 10 mm, and include copper, aluminum, stainless steel or their alloys. In this embodiment, the metal plate 21 is a copper sheet with a thickness of 2 mm. Each of the cavities 211 can have different size and cavity depth. The cavity depth can range from 0.05 mm to 1.0 mm. In this illustration, the cavity 211 is 0.26 mm (to house the 0.2 mm chip with 0.05 mm bump).

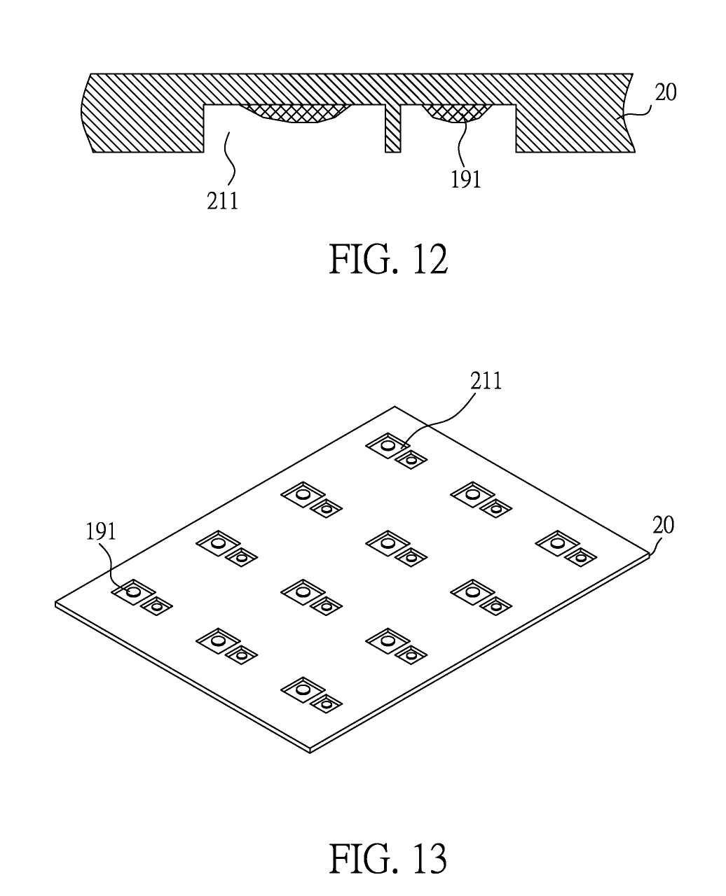

FIGS. 12 and 13 are cross-sectional and bottom perspective views, respectively, of the heat spreader 20 with a first adhesive 191 dispensed in the cavities 211. The first adhesive 191 typically is a thermally conductive adhesive and dispensed on the bottom of the cavities 211.

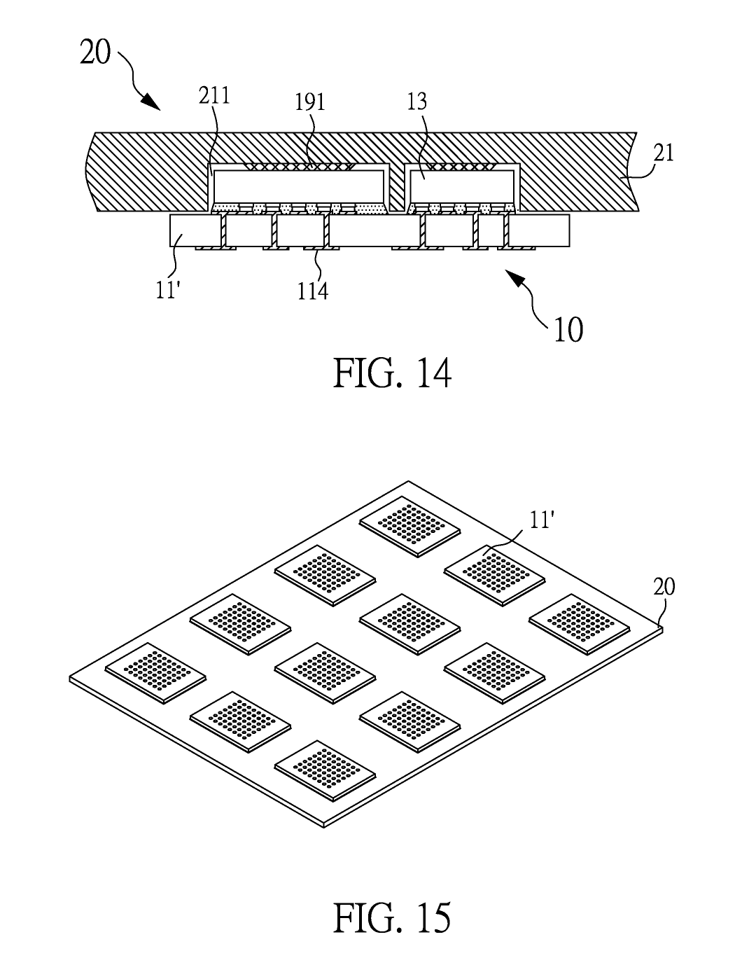

FIGS. 14 and 15 are cross-sectional and bottom perspective views, respectively, of the structure with the chip-on-interposer subassemblies 10 attached on the heat spreader 20 using the first adhesive 191. The chips 13 are inserted into the cavities 211, and the interposers 11′ are located beyond the cavities 211 and spaced from peripheral edges of the heat spreader 20.

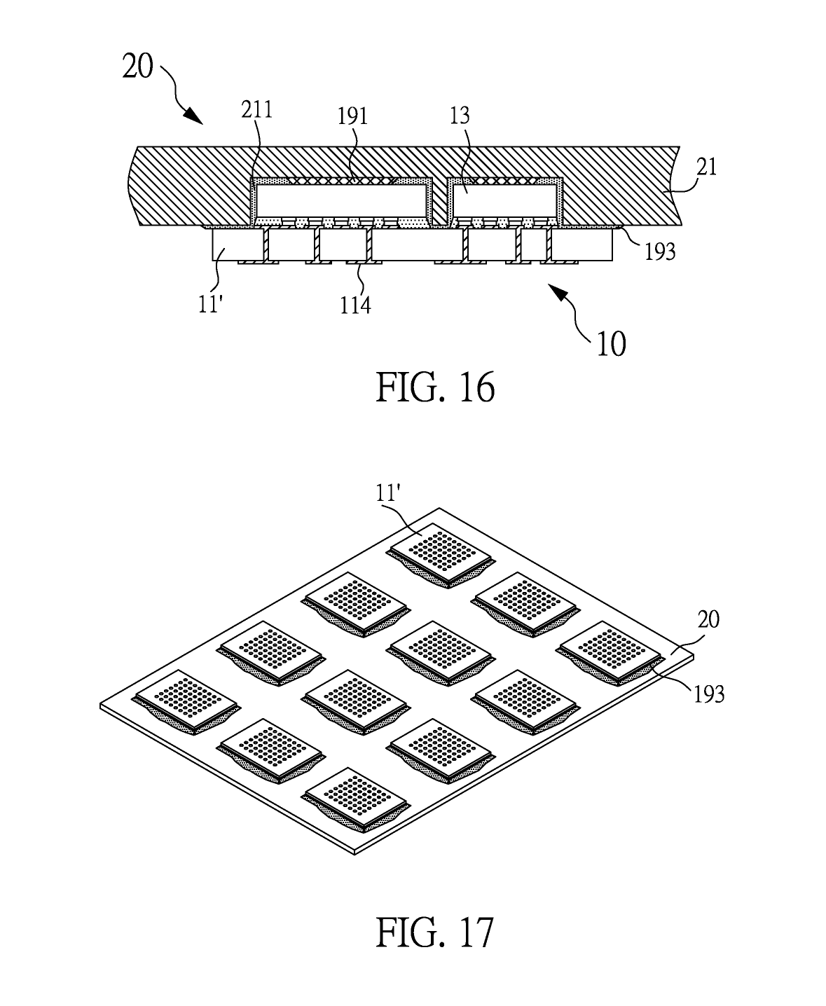

FIGS. 16 and 17 are cross-sectional and bottom perspective views, respectively, of the structure with a second adhesive 193 that fills the space between the interposers 11′ and the heat spreader 20 and further extends into the cavities 211. The second adhesive 193 typically is an electrically insulating underfill and dispensed into the space between the interposers 11′ and the heat spreader 20 and the remaining spaces within the cavities 211. As a result, the first adhesive 191 provides mechanical bonds and thermal connection between the chips 13 and the heat spreader 20, and the second adhesive 193 provides mechanical bonds between the chips 13 and the heat spreader 20 and between the interposers 11′ and the heat spreader 20.

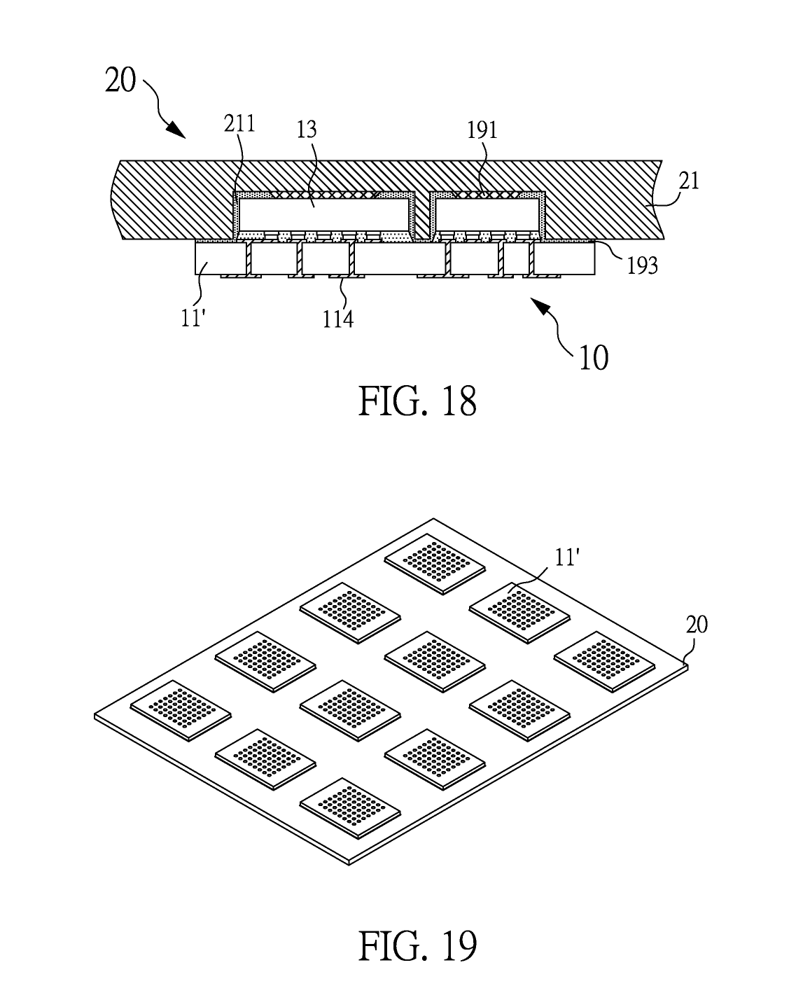

FIGS. 18 and 19 are cross-sectional and bottom perspective views, respectively, of the structure after removal of excess adhesive that flows out of the space between the interposers 11′ and the heat spreader 20. As an alternative, the step of removing excess adhesive may be omitted, and the excess adhesive becomes a portion of the subsequent buildup circuitry.

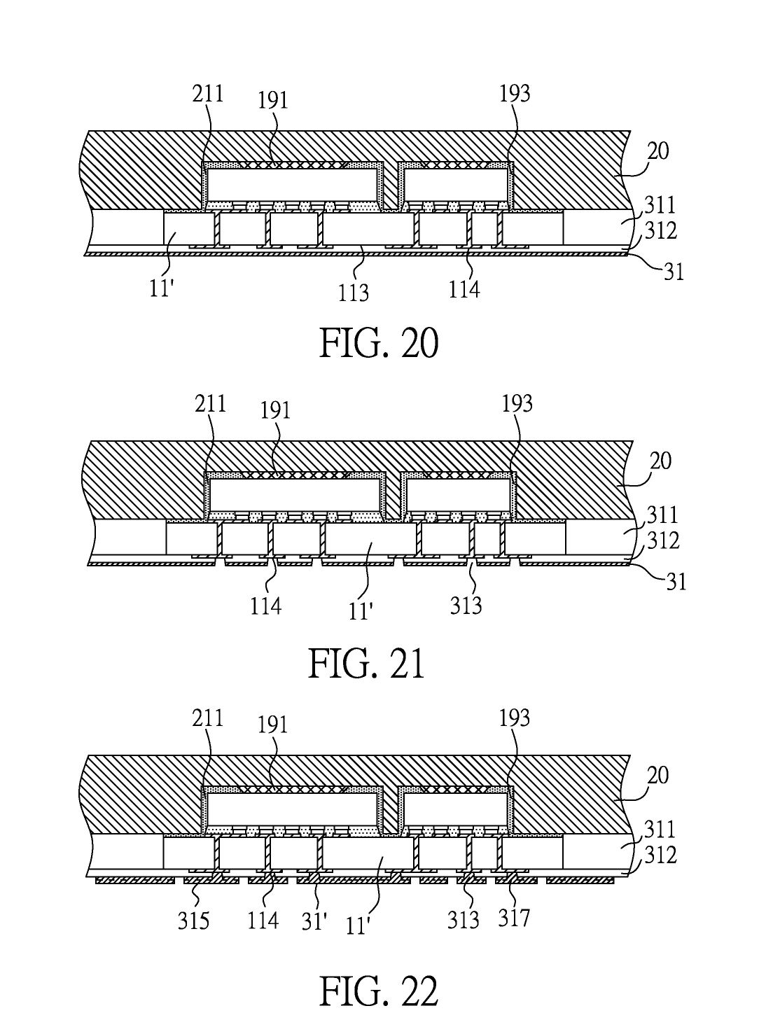

FIG. 20 is a cross-sectional view of the structure with a balancing layer 311, a first insulating layer 312 and a first metal sheet 31 laminated/coated on the interposers 11′ and the heat spreader 20 in the downward direction. The balancing layer 311 contacts and extends from the heat spreader 20 in the downward direction and laterally covers and surrounds and conformally coats the sidewalls of the interposers 11′ and extends laterally from the interposers 11′ to the peripheral edges of the structure. The first insulating layer 312 contacts and covers and extends laterally on the second surface 113 of the interposers 11′ and the balancing layer 311 in the downward direction. The first metal sheet 31 contacts and covers the first insulating layer 312 from below. In this illustration, the balancing layer 311 has a thickness of 0.2 mm which is close to the thickness of the interposer 11′, and the first insulating layer 312 typically has a thickness of 50 microns. The balancing layer 311 and the first insulating layer 312 can be made of epoxy resin, glass-epoxy, polyimide and the like. The first metal sheet 31 in this embodiment is a copper layer with a thickness of 25 microns.

FIG. 21 is a cross-sectional view of the structure provided with first via openings 313. The first via openings 313 extend through the first metal sheet 31 and the first insulating layer 312 and are aligned with the second contact pads 114 of the interposer 11′. The first via openings 313 may be formed by numerous techniques including laser drilling, plasma etching and photolithography, and typically have a diameter of 50 microns. Laser drilling can be enhanced by a pulsed laser. Alternatively, a scanning laser beam with a metal mask can be used. For instance, copper can be etched first to create a metal window followed by laser.

Referring now to FIG. 22, first conductive traces 315 are formed on the first insulating layer 312 by depositing a first plated layer 31′ on the first metal sheet 31 and into the first via openings 313, and then patterning the first metal sheet 31 as well as the first plated layer 31′ thereon. Alternatively, when no first metal sheet 31 is laminated on the first insulating layer 312 in the previous process, the first insulating layer 312 can be directly metallized to form the first conductive traces 315. The first conductive traces 315 extend from the first insulating layer 312 in the downward direction, extend laterally on the first insulating layer 312 and extend into the first via openings 313 in the upward direction to form first conductive vias 317 in direct contact with the second contact pads 114 of the interposer 11′. As a result, the first conductive traces 315 can provide horizontal signal routing in both the X and Y directions and vertical routing through the first via openings 313 and serve as electrical connections for the interposer 11′.

The first plated layer 31′ can be deposited by numerous techniques including electroplating, electroless plating, evaporating, sputtering, and their combinations as a single layer or multiple layers. For instance, it is deposited by first dipping the structure in an activator solution to render the first insulating layer 312 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the first conductive traces 315 by numerous techniques including wet etching, electro-chemical etching, laser-assist etching, and their combinations with an etch masks (not shown) thereon that define the first conductive traces 315.

The first metal sheet 31 and the first plated layer 31′ are shown as a single layer for convenience of illustration. The boundary between the metal layers may be difficult or impossible to detect since copper is plated on copper. However, the boundaries between the first plated layer 31′ and the first insulating layer 312 are clear.

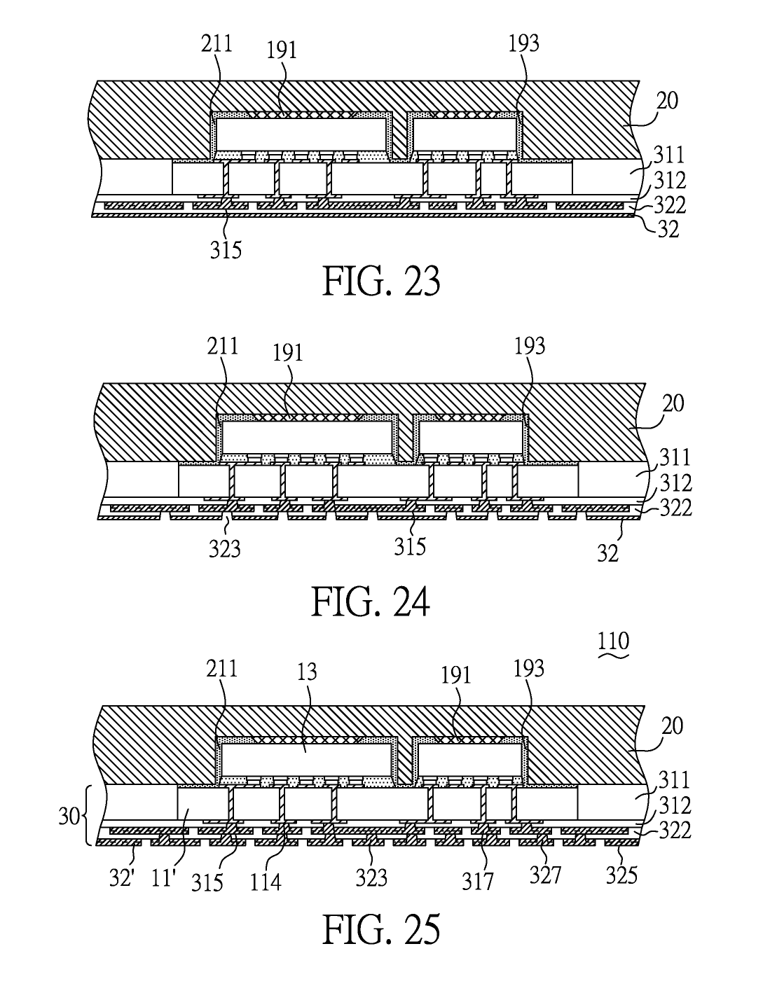

FIG. 23 is a cross-sectional view of the structure with a second insulating layer 322 and a second metal sheet 32 laminated/coated on the first insulating layer 312 and the first conductive traces 315. The second insulating layer 322 sandwiched between the first insulating layer 312/the first conductive traces 315 and the second metal sheet 32 can be formed of epoxy resin, glass-epoxy, polyimide and the like and typically has a thickness of 50 microns. The second metal sheet 32 in this embodiment is a copper layer with a thickness of 25 microns. Preferably, the first insulating layer 312 and the second insulating layer 322 are formed of the same material.

FIG. 24 is a cross-sectional view of the structure provided with second via openings 323 to expose selected portions of the first conductive traces 315. The second via openings 323 extend through the second metal sheet 32 and the second insulating layer 322. Like the first via openings 313, the second via openings 323 can be formed by numerous techniques including laser drilling, plasma etching and photolithography and typically have a diameter of 50 microns. Preferably, the first via openings 313 and the second via openings 323 have the same size.

Referring now to FIG. 25, second conductive traces 325 are formed on the second insulating layer 322 by depositing a second plated layer 32′ on the second metal sheet 32 and into the second via openings 323, and then patterning the second metal sheet 32 as well as the second plated layer 32′ thereon. Alternatively, when no second metal sheet 32 is laminated on the second insulating layer 322 in the previous process, the second insulating layer 322 can be directly metallized to form the second conductive traces 325. The second conductive traces 325 extend from the second insulating layer 322 in the downward direction, extend laterally on the second insulating layer 322 and extend into the second via openings 323 in the upward direction to form second conductive vias 327 in electrical contact with the first conductive traces 315. Preferably, the first conductive traces 315 and the second conductive traces 325 are formed of the same material with the same thickness.

Accordingly, as shown in FIG. 25, a semiconductor device 110 is accomplished and includes an inorganic interposer 11′, chips 13, a heat spreader 20 and a resin buildup circuitry 30. In this illustration, the buildup circuitry 30 includes a balancing layer 311, a first insulating layer 312, first conductive traces 315, a second insulating layer 322 and second conductive traces 325. The chips 13 are electrically coupled to the pre-fabricated interposer 11′ by flip chip process to form a chip-on-interposer subassembly 10. The chip-on-interposer subassembly 10 is attached on the heat spreader 20 using first and second adhesives 191, 193 with the chips 13 positioned within the cavities 211 and the interposer 11′ laterally extending beyond the cavities 211. The first adhesive 191 provides mechanical bonds and thermal connection between the chips 13 and the heat spreader 20, and the second adhesive 193 provides mechanical bonds between the chips 13 and the heat spreader 20 and between the interposer 11′ and the heat spreader 20. The buildup circuitry 30 is electrically coupled to the interposer 11′ through the first conductive vias 317 in direct contact with the second contact pads 114 of the interposer 11′ without soldering material. As such, the routing interconnection for the chips 13 is provided by the hybrid substrate consisting of the inorganic interposer 11′ and the resin buildup circuitry 30, and the CTE-matched interface between the chips 13 and the inorganic interposer 11′ of the hybrid substrate can improve the device's reliability.

### Embodiment 2

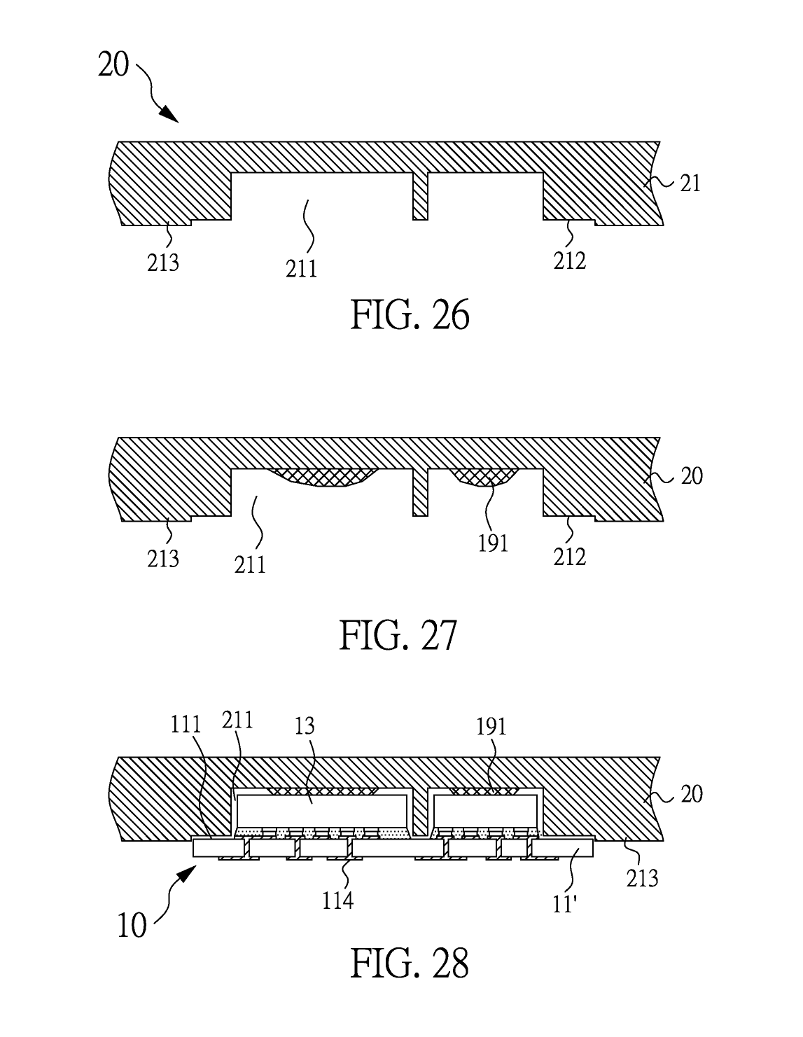

FIGS. 26-33 are cross-sectional views showing a method of making another semiconductor device with an alignment guide beyond the cavity for interposer attachment and additional conductive vias in contact with the heat spreader in accordance with another embodiment of the present invention.

For purposes of brevity, any description in Embodiment 1 above is incorporated herein insofar as the same is applicable, and the same description need not be repeated.

FIG. 26 is a cross-sectional view of a heat spreader 20 with an alignment guide 213 around the entrance of the cavities 211. The alignment guide 213 can be formed by removing selected portions of a metal plate 21 or by pattern deposition of a metal or plastic material on the metal plate 21. Plating, etching or mechanical carving is typically used to form the alignment guide 213. Accordingly, the alignment guide 213 extends from the flat surface 212 of the heat spreader 20 adjacent to the cavity entrance in the downward direction and can have a thickness of 5 to 200 microns. In this embodiment, the alignment guide 213 with a thickness of 50 microns laterally extends to the peripheral edges of the heat spreader 20 and has inner peripheral edges that conforms to the four lateral sides of a subsequently disposed interposer.

FIG. 27 is a cross-sectional view of the heat spreader 20 with a first adhesive 191 dispensed in the cavities 211. The first adhesive 191 typically is a thermally conductive adhesive and dispensed on the bottom of the cavities 211.

FIG. 28 is a cross-sectional view of the structure with a chip-on-interposer subassembly 10 attached on the heat spreader 20 using the first adhesive 191. The interposer 11′ and the chips 13 are attached on the heat spreader 20 with the chips 13 inserted into the cavities 211 and the alignment guide 213 laterally aligned with and in close proximity to the peripheral edges of the interposer 11′. The interposer placement accuracy is provided by the alignment guide 213. The alignment guide 213 extends beyond the first surface 111 of the interposer 11′ in the downward direction and is located beyond and laterally aligned with the four lateral surfaces of the interposer 11′ in the lateral directions. As the alignment guide 213 is in close proximity to and conforms to the four lateral surfaces of the interposer 11′ in lateral directions, any undesirable movement of the chip-on-interposer subassembly 10 due to adhesive curing can be avoided. Preferably, a gap in between the interposer 11′ and the alignment guide 213 is in a range of about 5 to 50 microns. The interposer 11′ can also be attached without the alignment guide 213. Although the cavities 211 cannot provide placement accuracy for the chip-on-interposer subassembly 10 due to control difficulties in cavity size and depth, it does not result in micro-via connection failure in the subsequent process of forming a buildup circuitry on the interposer 11′ due to the larger pad size and pitch of the interposer 11′.

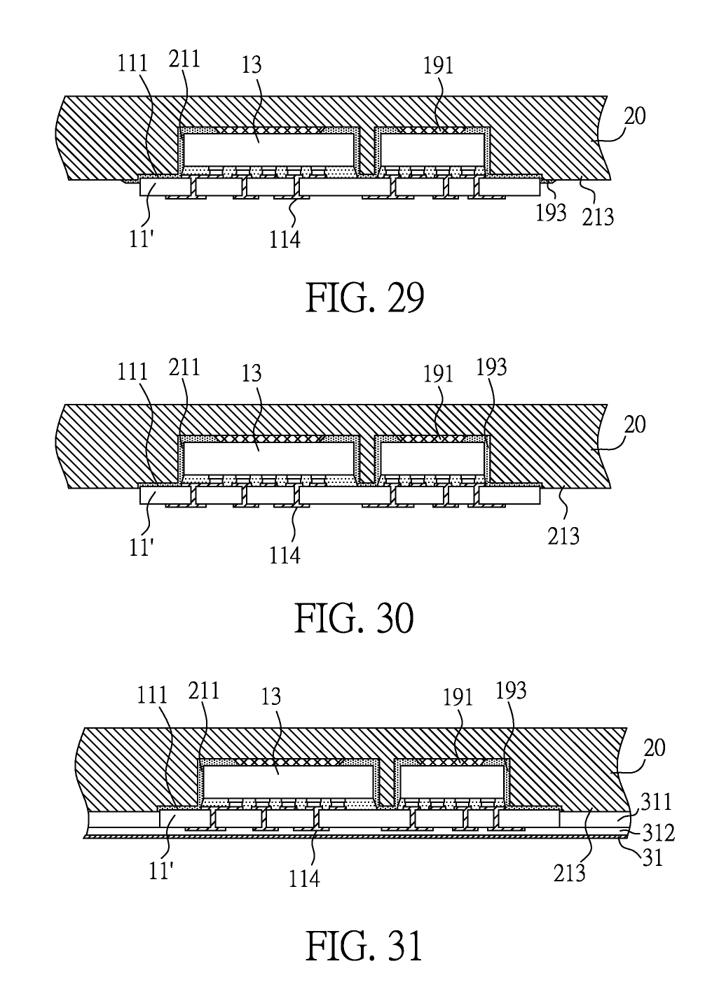

FIG. 29 is a cross-sectional view of the structure with a second adhesive 193 that fills the space between the interposer 11′ and the heat spreader 20 and further extends into the cavities 211. The second adhesive 193 typically is an electrically insulating underfill and dispensed into the space between the interposer 11′ and the heat spreader 20 and the remaining spaces within the cavities 211.

FIG. 30 is a cross-sectional view of the structure after removal of excess adhesive that overflows onto the alignment guide 213. As an alternative, the step of removing excess adhesive may be omitted, and the excess adhesive becomes a portion of the subsequent buildup circuitry.

FIG. 31 is a cross-sectional view of the structure with a balancing layer 311, a first insulating layer 312 and a first metal sheet 31 laminated/coated on the interposer 11′ and the heat spreader 20. The balancing layer 311 contacts and extends from the heat spreader 20 in the downward direction and laterally covers and surrounds and conformally coats the sidewalls of the interposer 11′ and extends laterally from the interposer 11′ to the peripheral edges of the structure. The first insulating layer 312 contacts and provides robust mechanical bonds between the first metal sheet 31 and the interposer 11′ and between the first metal sheet 31 and the balancing layer 311.

FIG. 32 is a cross-sectional view of the structure provided with first via openings 313, 314. The first via openings 313 extend through the first metal sheet 31 and the first insulating layer 312 and are aligned with the second contact pads 114 of the interposer 11′. Further, the additional first via openings 314 extend through the first metal sheet 31, the first insulating layer 312 and the balancing layer 311 and are aligned with selected portions of the heat spreader 20.

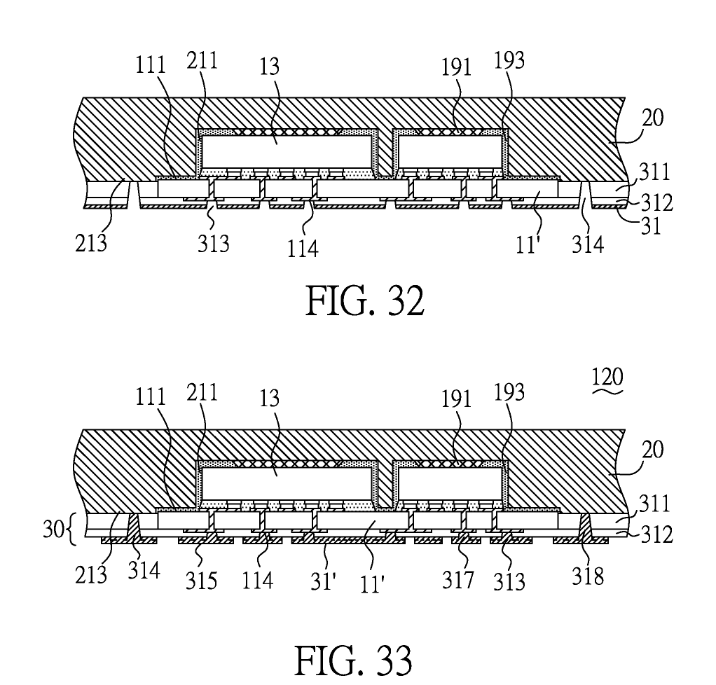

Referring now to FIG. 33, first conductive traces 315 are formed on the first insulating layer 312 by depositing a first plated layer 31′ on the first metal sheet 31 and into the first via openings 313, 314, and then patterning the first metal sheet 31 as well as the first plated layer 31′ thereon. The first conductive traces 315 extend from the first insulating layer 312 in the downward direction, extend laterally on the first insulating layer 312 and extend into the first via openings 313, 314 in the upward direction to form first conductive vias 317, 318 in direct contact with the second contact pads 114 of the interposer 11′ and selected portions of the heat spreader 20. As a result, the first conductive traces 315 can provide signal routings for the interposer 11′ and ground connection for the heat spreader 20.

Accordingly, as shown in FIG. 33, a semiconductor device 120 is accomplished and includes an inorganic interposer 11′, chips 13, a heat spreader 20 and a resin buildup circuitry 30. In this illustration, the buildup circuitry 30 includes a balancing layer 311, a first insulating layer 312 and first conductive traces 315. The chips 13 are electrically coupled to the pre-fabricated interposer 11′ by flip chip process to form a chip-on-interposer subassembly 10. The chip-on-interposer subassembly 10 is attached on the heat spreader 20 using first and second adhesives 191, 193 with the chips 13 positioned within the cavities 211 and the interposer 11′ laterally extending beyond the cavities 211. The first adhesive 191 provides mechanical bonds and thermal connection between the chips 13 and the heat spreader 20, and the second adhesive 193 provides mechanical bonds between the chips 13 and the heat spreader 20 and between the interposer 11′ and the heat spreader 20. The alignment guide 213 of the heat spreader 20 extends beyond the first surface 111 of the interposer 11′ in the downward direction and is in close proximity to the peripheral edges of the interposer 11′ to provide critical placement accuracy for the interposer 11′. The buildup circuitry 30 is electrically coupled to the interposer 11′ and the heat spreader 20 through the first conductive vias 317, 318 in direct contact with the second contact pads 114 of the interposer 11′ and selected portions of the heat spreader 20.

### Embodiment 3

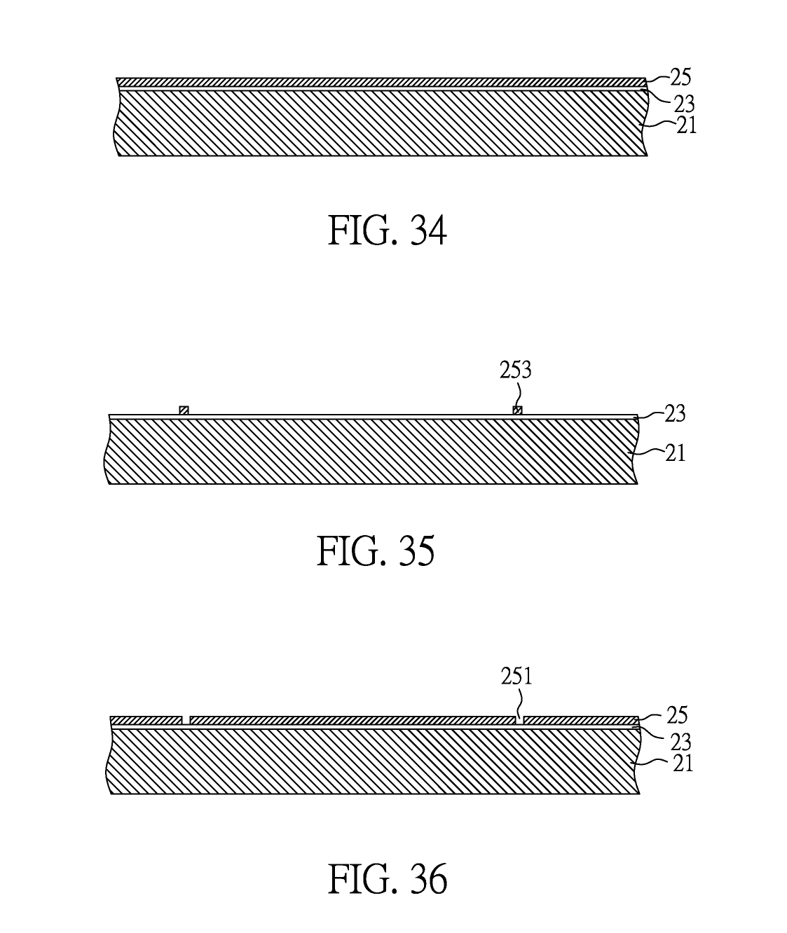

FIGS. 34-42 are cross-sectional views showing a method of making yet another semiconductor device with an laminate substrate as the heat spreader in accordance with yet another embodiment of the present invention.

For purposes of brevity, any description in the aforementioned Embodiments is incorporated herein insofar as the same is applicable, and the same description need not be repeated.

FIGS. 34 and 35 are cross-sectional views showing a process of forming an alignment guide on a dielectric layer of a laminated substrate in accordance with an embodiment of the present invention.

FIG. 34 is a cross-sectional view of a laminate substrate that includes a metal plate 21, a dielectric layer 23 and a metal layer 25. The dielectric layer 23 is sandwiched between the metal plate 21 and the metal layer 25. The dielectric layer 23 typically is made of epoxy resin, glass-epoxy, polyimide and the like and has a thickness of 50 microns. The metal layer 25 typically is made of copper, but copper alloys or other materials (such as aluminum, stainless steel or their alloys) may also be used. The thickness of the metal layer 25 can range from 5 to 200 microns. In this embodiment, the metal layer 25 is a copper plate with a thickness of 50 microns.

FIG. 35 is a cross-sectional view of the structure with an alignment guide 253 formed on the dielectric layer 23. The alignment guide 253 can be formed by removing selected portions of the metal layer 25 using photolithography and wet etching. In this embodiment, the alignment guide 253 consists of plural metal posts in a rectangular frame array conforming to four lateral sides of a subsequently disposed interposer. However, the alignment guide patterns are not limited thereto and can be other various patterns against undesirable movement of the subsequently disposed interposer. For instance, the alignment guide 253 may consist of a continuous or discontinuous strip and conform to four sides, two diagonal corners or four corners of a subsequently disposed interposer.

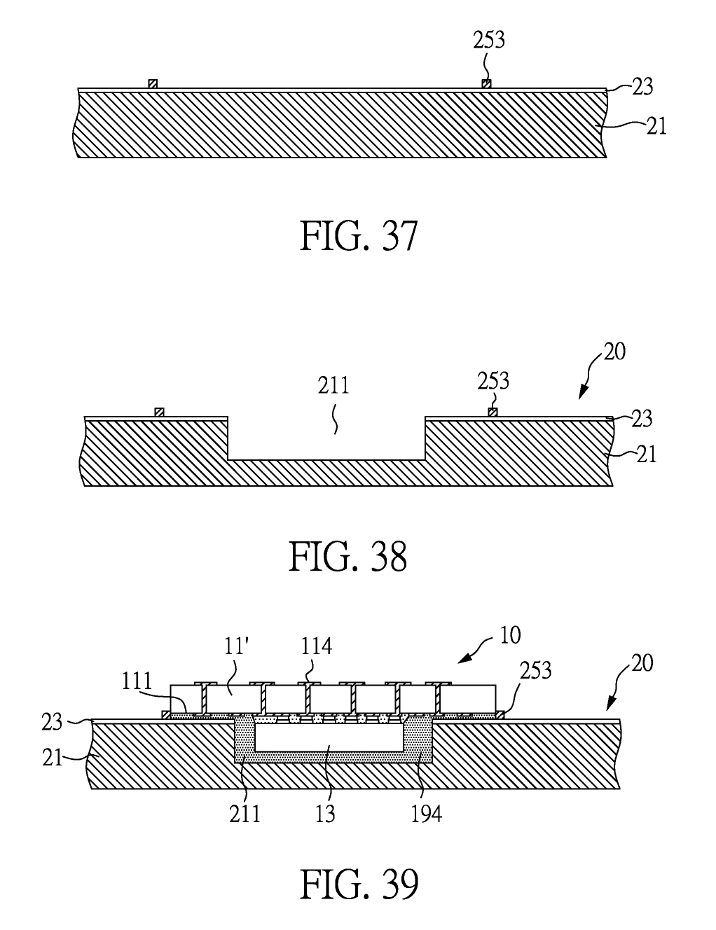

FIGS. 36 and 37 are cross-sectional views showing an alternative process of forming an alignment guide on a dielectric layer of a laminate substrate.

FIG. 36 is a cross-sectional view of a laminate substrate with a set of openings 251. The laminate substrate includes a metal plate 21, a dielectric layer 23 and a metal layer 25 as above mentioned, and the openings 251 are formed by removing selected portions of the metal layer 25.

FIG. 37 is a cross-sectional view of the structure with an alignment guide 253 formed on the dielectric layer 23. The alignment guide 253 can be formed by dispensing or printing a photosensitive plastic material (e.g., epoxy, polyimide, etc.) or non-photosensitive material into the openings 251, followed by removing the entire metal layer 25. Herein, the alignment guide 253 consists of plural resin posts and has a pattern against undesirable movement of a subsequently disposed interposer.

FIG. 38 is a cross-sectional view of the heat spreader 20 with a cavity 211. The cavity 211 extends through the dielectric layer 23 and further extends into the metal plate 21.

FIG. 39 is a cross-sectional view of the structure with a chip-on-interposer subassembly 10 attached on the heat spreader 20 using an adhesive 194. The chip-on-interposer subassembly 10 is similar to that illustrated in FIG. 5, except that a single chip 13 is flip mounted on the interposer 11′ in this illustration. The chip 13 is positioned within the cavity 211, and the interposer 11′ is located beyond the cavity 211 with its first surface 111 attached on the dielectric layer 23. The chip 13 is mounted on the heat spreader 20 by dispensing the adhesive 194 on the bottom of the cavity 211, and then inserting the chip 13 of the chip-on-interposer subassembly 10 into the cavity 211. The adhesive 194 (typically a thermally conductive but electrically insulating adhesive) within the cavity 211 is compressed by the chip 13, flows upward into the gaps between the chip 13 and the cavity sidewalls, and overflows onto the flat surface of the dielectric layer 23. As a result, the adhesive 194 surrounds the embedded chip 13, and the squeezed out portion also serves as the interposer attach adhesive. The alignment guide 253 extends from the dielectric layer 23 and extends beyond the first surface 111 of the interposer 11′ in the upward direction and is in close proximity to the peripheral edges of the interposer 11′ to provide critical placement accuracy for the interposer 11′.

FIG. 40 is a cross-sectional view of the structure with a balancing layer 311, a first insulating layer 312 and a first metal sheet 31 laminated/coated on the interposer 11′ and the heat spreader 20. The balancing layer 311 contacts and covers the dielectric layer 23 of the heat spreader 20 and the sidewalls of the interposer 11′. The first insulating layer 312 contacts and provides robust mechanical bonds between the first metal sheet 31 and the interposer 11′ and between the first metal sheet 31 and the balancing layer 311.

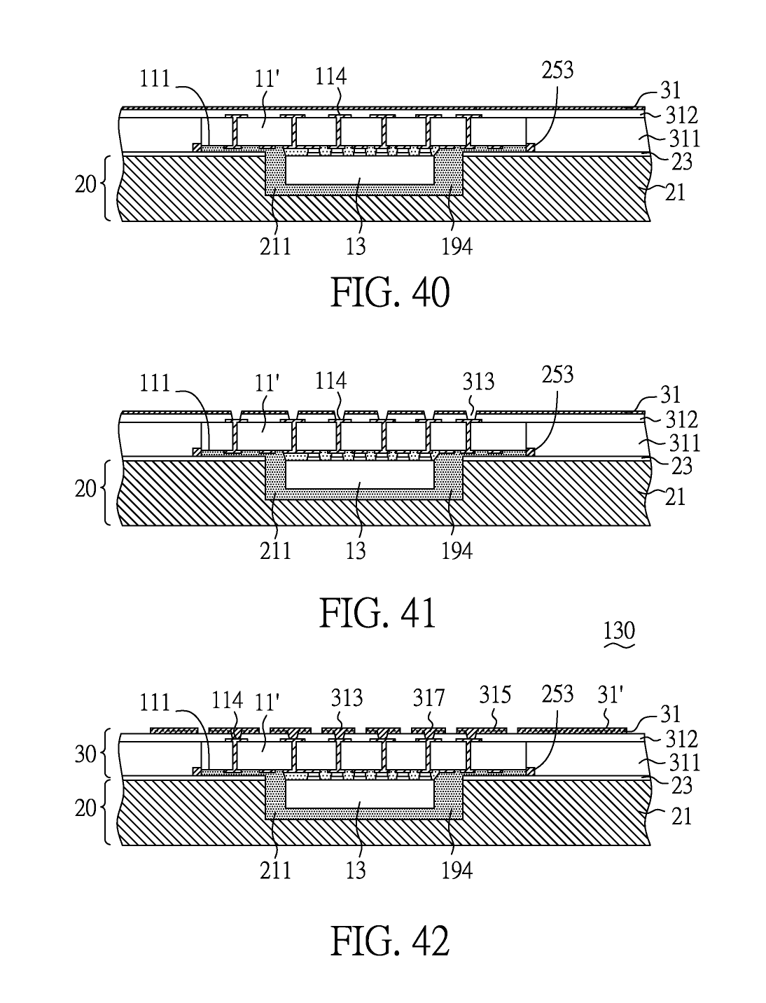

FIG. 41 is a cross-sectional view of the structure provided with first via openings 313. The first via openings 313 extend through the first metal sheet 31 and the first insulating layer 312 and are aligned with the second contact pads 114 of the interposer 11′.

Referring now to FIG. 42, first conductive traces 315 are formed on the first insulating layer 312 by depositing a first plated layer 31′ on the first metal sheet 31 and into the first via openings 313, and then patterning the first metal sheet 31 as well as the first plated layer 31′ thereon. The first conductive traces 315 extend from the first insulating layer 312 in the upward direction, extend laterally on the first insulating layer 312 and extend into the first via openings 313 in the downward direction to form first conductive vias 317 in direct contact with the second contact pads 114 of the interposer 11′. As a result, the first conductive traces 315 can provide signal routings for the interposer 11′.

Accordingly, as shown in FIG. 42, a semiconductor device 130 is accomplished and includes an inorganic interposer 11′, a chip 13, a heat spreader 20 and a resin buildup circuitry 30. The chip 13 is electrically coupled to the pre-fabricated interposer 11′ by flip chip process to form a chip-on-interposer subassembly 10. The heat spreader 20 includes a cavity 211 that extends through the dielectric layer 23 and extends into the metal plate 21. The chip-on-interposer subassembly 10 is attached on the heat spreader 20 using an adhesive 194 with the chip 13 positioned within the cavity 211 and the interposer 11′ laterally extending beyond the cavity 211. The adhesive 194 surrounds the embedded chip 13, and the squeezed out portion contacts and is sandwiched between the first surface 111 of the interposer 11′ and the dielectric layer 23 and serves as the interposer attach adhesive. The alignment guide 253 of the heat spreader 20 extends from the dielectric layer 23 and extends beyond the first surface 111 of the interposer 11′ in the upward direction and is in close proximity to the peripheral edges of the interposer 11′ to provide critical placement accuracy for the interposer 11′. The buildup circuitry 30 is electrically coupled to the interposer 11′ through the first conductive vias 317 in direct contact with the second contact pads 114 of the interposer 11′.

### Embodiment 4

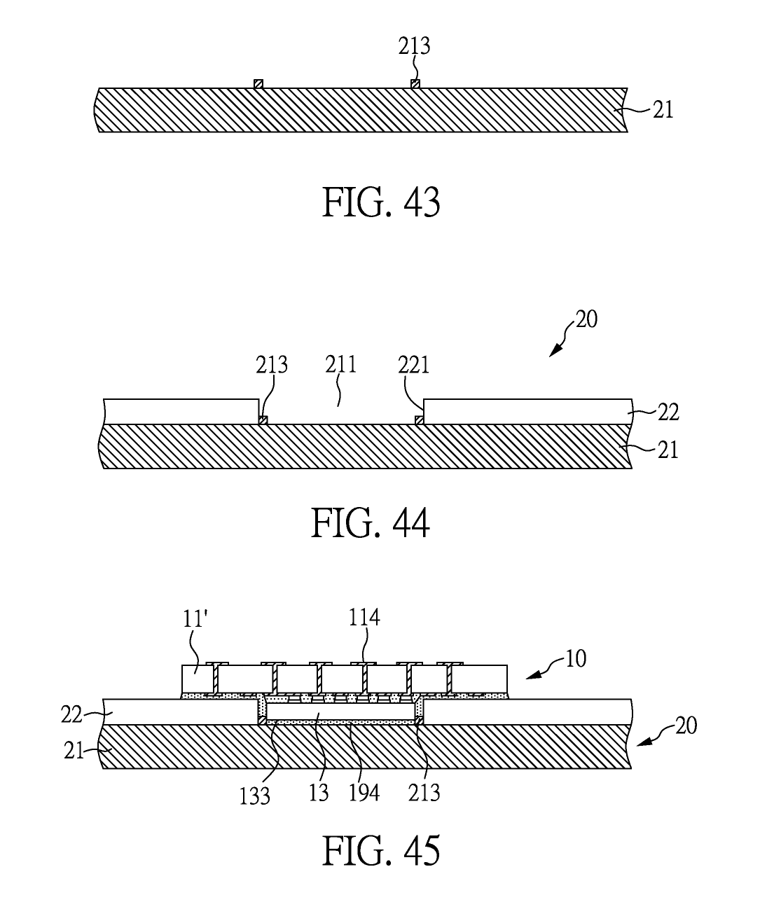

FIGS. 43-48 are cross-sectional views showing a method of making further another semiconductor device with an alignment guide within the cavity of the heat spreader in accordance with further another embodiment of the present invention.

For purposes of brevity, any description in the aforementioned Embodiments is incorporated herein insofar as the same is applicable, and the same description need not be repeated.

FIG. 43 is a cross-sectional view of the structure with an alignment guide 213 formed on a metal plate 21. The metal plate 21 in this embodiment is a copper sheet with a thickness of 1 mm. The alignment guide 213 can be formed by removing selected portions of the metal plate 21 or by pattern deposition of a metal or plastic material on the metal plate 21. In this embodiment, the alignment guide 213 consists of plural metal posts in a rectangular frame arrangement conforming to four sides of a subsequently disposed chip. However, the alignment guide patterns are not limited thereto and can be other various patterns against undesirable movement of the subsequently disposed chip.

FIG. 44 is a cross-sectional view of a heat spreader 20 with the alignment guide 213 inserted into an aperture 221 of a base layer 22. The base layer 22 is laminated onto the metal plate 21 with the alignment guide 213 aligned with and inserted into the aperture 221 of the base layer 22. The base layer 22 can be made of epoxy, BT, polyimide and other kinds of resin or resin/glass composite. In this illustration, the base layer 22 has a thickness of 0.21 mm to match 0.15 mm chip and 0.05 mm bump. As a result, a cavity 211 can be defined by the aperture 221 of the base layer 22 on the metal plate 21, and the alignment guide 213 is located on the bottom of the cavity 211.

FIG. 45 is a cross-sectional view of the structure with a chip-on-interposer subassembly 10 attached on the heat spreader 20 using an adhesive 194. The interposer 11′ and the chip 13 are attached on the heat spreader 20 with chip 13 inserted into the cavity 211 and the alignment guide 213 laterally aligned with peripheral edges of the chip 13. The adhesive 194 surrounds the embedded chip 13, and the squeezed out portion contacts and is sandwiched between the first surface 111 of the interposer 11′ and the base layer 22. The alignment guide 213 extends from the bottom of the cavity 211 and extends beyond the inactive surface 133 of the chip 13 in the upward direction and is in close proximity to the peripheral edges of the chip 13 to provide critical placement accuracy for the chip-on-interposer subassembly 10.

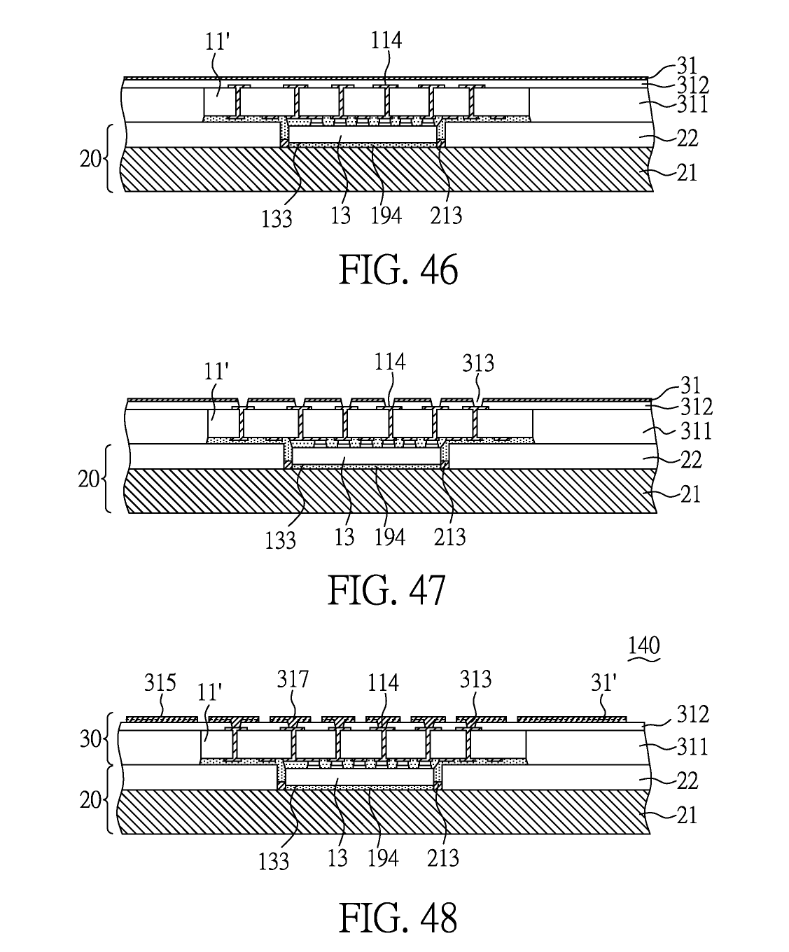

FIG. 46 is a cross-sectional view of the structure with a balancing layer 311, a first insulating layer 312 and a first metal sheet 31 laminated/coated on the interposer 11′ and the heat spreader 20. The balancing layer 311 contacts and covers the base layer 22 of the heat spreader 20 and the sidewalls of the interposer 11′. The first insulating layer 312 contacts and provides robust mechanical bonds between the first metal sheet 31 and the interposer 11′ and between the first metal sheet 31 and the balancing layer 311.

FIG. 47 is a cross-sectional view of the structure provided with first via openings 313. The first via openings 313 extend through the first metal sheet 31 and the first insulating layer 312 and are aligned with the second contact pads 114 of the interposer 11′.

Referring now to FIG. 48, first conductive traces 315 are formed on the first insulating layer 312 by depositing a first plated layer 31′ on the first metal sheet 31 and into the first via openings 313, and then patterning the first metal sheet 31 as well as the first plated layer 31′ thereon. The first conductive traces 315 extend from the first insulating layer 312 in the upward direction, extend laterally on the first insulating layer 312 and extend into the first via openings 313 in the downward direction to form first conductive vias 317 in direct contact with the second contact pads 114 of the interposer 11′.

Accordingly, as shown in FIG. 48, a semiconductor device 140 is accomplished and includes an inorganic interposer 11′, a chip 13, a heat spreader 20 and a resin buildup circuitry 30. The chip 13 is electrically coupled to the pre-fabricated interposer 11′ by flip chip process to form a chip-on-interposer subassembly 10. The chip-on-interposer subassembly 10 is attached on the heat spreader 20 using an adhesive 194 with the chip 13 positioned within the cavity 211 and the alignment guide 213 laterally aligned with and in close proximity to the peripheral edges of the chip 13. The adhesive 194 contacts and provides robust mechanical bonds between the interposer 11′ and the heat spreader 20 and between the chip 13 and the heat spreader 20. The buildup circuitry 30 is electrically coupled to the interposer 11′ through the first conductive vias 317 and provides fan out routing/interconnection.

The assemblies described above are merely exemplary. Numerous other embodiments are contemplated. In addition, the embodiments described above can be mixed-and-matched with one another and with other embodiments depending on design and reliability considerations. The chip can share or not share the cavity with other chips. For instance, a cavity can accommodate a single chip, and the heat spreader can include multiple cavities arranged in an array for multiple chips. Alternatively, numerous chips can be positioned within a single cavity. Likewise, a chip can share or not share the interposer with other chips. For instance, a single chip can be electrically connected to the interposer. Alternatively, numerous chips may be coupled to the interposer. For instance, four small chips in a 2×2 array can be coupled to the interposer and the interposer can include additional contact pads to receive and route additional chip pads. Also, the buildup circuitry can include additional conductive traces to accommodate additional contact pads of the interposer.

As illustrated in the aforementioned embodiments, a distinctive semiconductor device is configured to exhibit improved thermal performance and reliability, which includes a chip, a heat spreader, an adhesive, and a two-step formed hybrid substrate consisting of an inorganic interposer and a buildup circuitry.

The chip can be a packaged or unpackaged chip. Furthermore, the chip can be a bare chip, or a wafer level packaged die, etc.

The heat spreader can extend to the peripheral edges of the device to provide mechanical support for the chip, the inorganic interposer and the buildup circuitry. In a preferred embodiment, the heat spreader includes a metal plate to provide essential thermal dissipation for the embedded chip. The metal plate can have a thickness of 0.1 mm to 10 mm. The material of the metal plate can be selected for the thermal dissipation consideration, and include copper, aluminum, stainless steel or their alloys. The heat spreader can be a single-layer structure or multi-layer structure, and includes a cavity extending into the metal plate or defined by an aperture of a base layer on the metal plate. For instance, the heat spreader may be a metal plate with a cavity defined therein and a flat surface that laterally extends from the cavity entrance. Alternatively, the heat spreader may be a laminate substrate including a metal plate and a dielectric layer, and has a cavity that extends through the dielectric layer and extends into the metal plate. Also, the heat spreader may include a metal plate and a base layer with an aperture, and the cavity is defined by the aperture of the base layer on the metal plate. As such, the heat from the chip can be dissipated through the metal plate that provides a thermal contact surface at the cavity bottom. For the heat spreader with the cavity defined in the metal plate, the metallic sidewalls of the cavity also can serve as additional thermal contact surface for the chip in addition to the metallic bottom of the cavity.

Moreover, the heat spreader may further include an alignment guide beyond or within the cavity for the interposer attachment. For the aspect of the heat spreader with the alignment guide beyond the cavity, the alignment guide extends from a flat surface of the heat spreader adjacent to the cavity entrance and extends beyond the first surface of the interposer in the second vertical direction (for the convenience of description, the direction in which the first surface of the interposer faces is defined as the first vertical direction, and the direction in which the second surface of the interposer faces is defined as the second vertical direction). As for another aspect of the heat spreader with the alignment guide within the cavity, the alignment guide extends from the flat surface of the metal plate at the cavity bottom and extends beyond the inactive surface of the flip chip in the second vertical direction. As such, the interposer placement accuracy can be provided by the alignment guide that is laterally aligned with and in close proximity to the peripheral edges of the interposer or the chip.

The alignment guide can be made of a metal, a photosensitive plastic material or non-photosensitive material. For instance, the alignment guide can consist essentially of copper, aluminum, nickel, iron, tin or their alloys. The alignment guide can also include or consist of epoxy or polyimide. Further, the alignment guide can have patterns against undesirable movement of the interposer or the chip. For instance, the alignment guide can include a continuous or discontinuous strip or an array of posts. Alternatively, the alignment guide may laterally extend to the peripheral edges of the heat spreader and have inner peripheral edges that conforms to the peripheral edges of the interposer or the chip. Specifically, the alignment guide can be laterally aligned with four lateral surfaces of the interposer or the chip to define an area with the same or similar topography as the interposer or the chip and prevent the lateral displacement of the interposer or the chip. For instance, the alignment guide can be aligned along and conform to four sides, two diagonal corners or four corners of the interposer or the chip, and the gaps in between the interposer and the alignment guide or between the chip and the alignment guide preferably is in a range of about 5 to 50 microns. As a result, the alignment guide located beyond the interposer or the chip can provide placement accuracy for the chip-on-interposer subassembly. Besides, the alignment guide preferably has a height in a range of 5-200 microns.

The cavity of the heat spreader can have a larger diameter or dimension at its entrance than at its bottom and a depth of 0.05 mm to 1.0 mm. For instance, the cavity can have a cut-off conical or pyramidal shape in which its diameter or dimension increases as it extends in the second vertical direction from its bottom to its entrance. Alternatively, the cavity can have a cylindrical shape with a constant diameter. The cavity can also have a circular, square or rectangular periphery at its entrance and its bottom.

The adhesive can be dispensed on the cavity bottom and then be squeezed partially out of the cavity when inserting the chip into the cavity. Accordingly, the adhesive can contact and surround the embedded chip within the cavity of the heat spreader, and the squeezed out portion can contact and be sandwiched between the first surface of the interposer and the flat surface of the heat spreader that laterally extends from the cavity entrance. Alternatively, a thermally conductive adhesive can be dispensed on the cavity bottom and be contained within the cavity when inserting the chip into the cavity. A second adhesive (typically an electrically insulating underfill) can then be dispensed and filled into the remaining space within the cavity and extends to the space between the first surface of the interposer and the flat surface of the heat spreader that laterally extends from the cavity entrance. Accordingly, the first adhesive provides mechanical bonds and thermal connection between the chip and the heat spreader while the second adhesive provides mechanical bonds between the interposer and the heat spreader.

The inorganic interposer laterally extends beyond the cavity and can be attached to the flat surface of the heat spreader adjacent to the cavity entrance with its first surface facing the heat spreader. The inorganic interposer can be a silicon, glass, ceramic, or graphite material with a thickness of 50 to 500 microns, and can contain a pattern of traces that fan out from a fine pitch at the first contact pads to a coarse pitch at the second contact pads. Accordingly, the interposer can provide first level fan-out routing/interconnection for the embedded chip. Additionally, as the inorganic interposer is typically made of a high elastic modulus material with linear CTE closely matches to that of the chip (for example, Aluminum nitride is about 5.3×10⁻⁶ K⁻¹ and borosilicate glass is about 3.3×10⁻⁶ K⁻¹), internal stresses in chip and its electrical interconnection caused by CTE mismatch can be largely compensated or reduced.

The buildup circuitry is disposed adjacent to the second surface of the interposer and the heat spreader and can provide secondary fan-out routing/interconnection. Besides, the buildup circuitry can further be electrically coupled to the metallic surface of the heat spreader by additional conductive via for ground connection. The buildup circuitry includes a balancing layer, an insulating layer and one or more conductive traces. The balancing layer is deposited on the heat spreader and laterally covers sidewalls of the interposer. The insulating layer is deposited on the second surface of the interposer and the balancing layer. The conductive traces extend laterally on the insulating layer and extend through one or more via openings in the insulating layer to form one or more conductive vias in direct contact with the second contact pads of the interposer and optionally with the heat spreader. Accordingly, the conductive traces can directly contact the second contact pads to provide signal routing for the interposer, and thus the electrical connection between the interposer and the buildup circuitry can be devoid of soldering material.

The buildup circuitry can further include additional insulating layers, additional via openings, and additional conductive traces if needed for further signal routing. The outmost conductive traces of the buildup circuitry can have a patterned array of terminal pads to provide electrical contacts for the next level assembly or another electronic device such as a semiconductor chip, a plastic package or another semiconductor assembly. As a result, the next level assembly or another electronic device can be electrically connected to the embedded chip using a wide variety of connection media including gold or solder bumps on the electrical contacts (i.e. the terminal pads of the buildup circuitry).

The term “cover” refers to incomplete or complete coverage in a vertical and/or lateral direction. For instance, in the cavity-up position, the metal plate covers the chip in the downward direction regardless of whether another element such as the adhesive is between the metal plate and the chip.

The phrase “aligned with” refers to relative position between elements regardless of whether elements are spaced from or adjacent to one another or one element is inserted into and extends into the other element. For instance, the alignment guide is laterally aligned with the interposer since an imaginary horizontal line intersects the alignment guide and the interposer, regardless of whether another element is between the alignment guide and the interposer and is intersected by the line, and regardless of whether another imaginary horizontal line intersects the interposer but not the alignment guide or intersects the alignment guide but not the interposer. Likewise, the first via opening is aligned with the second contact pads of the interposer.

The phrase “in close proximity to” refers to a gap between elements not being wider than a maximum acceptable limit. As known in the art, when the gap between the alignment guide and the interposer is not narrow enough, the location error of the interposer due to the lateral displacement of the interposer within the gap may exceed the maximum acceptable error limit. In some cases, once the location error of the interposer goes beyond the maximum limit, it is impossible to align the predetermined portion of the interposer with a laser beam, resulting in the electrical connection failure between the interposer and the buildup circuitry. According to the pad size of the interposer, those skilled in the art can ascertain the maximum acceptable limit for a gap between the interposer and the alignment guide through trial and error to ensure the conductive vias being aligned with the contact pads of the interposer. Thereby, the descriptions “the alignment guide is in close proximity to the peripheral edges of the interposer” and “the alignment guide is in close proximity to the peripheral edges of the chip” mean that the gap between the alignment guide and the peripheral edges of the interposer or the chip is narrow enough to prevent the location error of the interposer from exceeding the maximum acceptable error limit.

The phrases “mounted on”, “attached on”, “attached onto”, “laminated on” and “laminated onto” include contact and non-contact with a single or multiple support element(s). For instance, the interposer can be attached on the heat spreader regardless of whether it contacts the heat spreader or is separated from the heat spreader by an adhesive.

The phrases “electrical connection”, “electrically connected”, “electrically coupled” and “electrically couples” refer to direct and indirect electrical connection. For instance, the first conductive trace provides an electrical connection between the terminal pad and the second contact pad of the interposer regardless of whether the first conductive trace is adjacent to the terminal pad or electrically connected to the terminal pad by the second conductive trace.

The “first vertical direction” and “second vertical direction” do not depend on the orientation of the device, as will be readily apparent to those skilled in the art. For instance, the first surface of the interposer faces the first vertical direction and the second surface of the interposer faces the second vertical direction regardless of whether the device is inverted. Likewise, the alignment guide is “laterally” aligned with the interposer or the chip in a lateral plane regardless of whether the device is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the cavity-up position, and the first vertical direction is the upward direction and the second vertical direction is the downward direction in the cavity-down position.

The semiconductor device according to the present invention has numerous advantages. For instance, the chip is electrically coupled to the interposer by a well-known flip chip bonding process such as thermo-compression or solder reflow, which can avoid the positional accuracy issue inherent to conventional approaches where an adhesive carrier is used for temporary bonding. The interposer which is typically made of high elastic modulus inorganic material provides robust primary fan-out routing/interconnection for the embedded chip whereas the resin buildup circuitry provides secondary fan-out routing/interconnection. As the buildup circuitry is formed on the interposer designed with larger pad size and pitch space, the manufacturing yield is greatly improved compared to the conventional types where buildup circuitry is directly formed on the chip I/O pad without fan-out routing. The alignment guide can provide critical placement accuracy for the interposer. As such, the shape or depth of the cavity that houses the embedded chip is not a critical parameter that needs tightly controlled. The heat spreader can provide thermal dissipation, electromagnetic shielding and moisture barrier for the embedded chip, and also provides mechanical support for the chip, the interposer and the buildup circuitry. The direct electrical connection without solder between the interposer and the buildup circuitry is advantageous to high I/O and high performance. The device made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a semiconductor device, comprising steps of:
providing a chip;
providing an inorganic interposer that includes through vias, a first surface, a second surface opposite to the first surface, first contact pads on the first surface and second contact pads on the second surface, wherein the through vias electrically couple the first contact pads and the second contact pads;
electrically coupling the chip to the first contact pads of the inorganic interposer by a plurality of bumps to provide a chip-on-interposer subassembly;
providing a heat spreader with a cavity;
attaching the chip-on-interposer subassembly on the heat spreader using an adhesive with the chip inserted into the cavity and the inorganic interposer laterally extending beyond the cavity; and then
forming a buildup circuitry on the heat spreader and the second surface of the inorganic interposer, wherein the buildup circuitry is electrically coupled to the second contact pads of the inorganic interposer through conductive vias of the buildup circuitry.

2. The method of claim 1, wherein the step of electrically coupling the chip to the first contact pads of the inorganic interposer is performed on a panel scale, and a singulation step is executed to separate individual chip-on-interposer subassemblies before the step of attaching the chip-on-interposer subassembly on the heat spreader.

3. The method of claim 1, wherein the heat spreader further includes an alignment guide beyond the cavity, and the chip-on-interposer subassembly is attached to the heat spreader with the alignment guide laterally aligned with and in close proximity to peripheral edges of the inorganic interposer.

4. The method of claim 3, wherein the step of providing the heat spreader includes:
providing a metal plate;
forming the cavity in the metal plate; and
forming the alignment guide around an entrance of the cavity by removing a selected portion of the metal plate or by pattern deposition of a metal or a plastic material on the metal plate.

5. The method of claim 3, wherein the step of providing the heat spreader includes:
providing a laminated substrate that includes a dielectric layer and a metal plate;
forming the alignment guide on the dielectric layer by removing a selected portion of a metal layer on the dielectric layer or by pattern deposition of a metal or a plastic material on the dielectric layer; and
forming the cavity that extends through the dielectric layer and optionally extends into the metal plate.

6. The method of claim 1, wherein the heat spreader further includes an alignment guide within the cavity, and the chip-on-interposer subassembly is attached to the heat spreader with the alignment guide laterally aligned with and in close proximity to peripheral edges of the chip.

7. The method of claim 6, wherein the step of providing the heat spreader includes:
providing a metal plate;
forming the alignment guide at a surface of the metal plate by removing a selected portion of the metal plate or by pattern deposition of a metal or a plastic material on the metal plate; and
providing a base layer on the metal plate with the alignment guide located within an aperture of the base layer.

8. The method of claim 1, wherein the step of forming the buildup circuitry includes electrically coupling the heat spreader to the buildup circuitry through additional conductive vias of the buildup circuitry.

9. A semiconductor device prepared by a method that comprises steps of:
providing a chip;
providing an inorganic interposer that includes through vias, a first surface, a second surface opposite to the first surface, first contact pads on the first surface and second contact pads on the second surface, wherein the through vias electrically couple the first contact pads and the second contact pads;
electrically coupling the chip to the first contact pads of the inorganic interposer by a plurality of bumps to provide a chip-on-interposer subassembly;
providing a heat spreader with a cavity;
attaching the chip-on-interposer subassembly on the heat spreader using an adhesive with the chip inserted into the cavity and the inorganic interposer laterally extending beyond the cavity; and then
forming a buildup circuitry on the heat spreader and the second surface of the inorganic interposer, wherein the buildup circuitry is electrically coupled to the second contact pads of the inorganic interposer through conductive vias of the buildup circuitry.
